(19) United States
(12) Patent Application Publication
(10) Pub. No.: US 2001/0044182 A1
(43) Pub. Date: Nov. 22, 2001

(54) SEMICONDUCTOR DEVICE HAVING HSG POLYCRYSTALLINE SILICON LAYER

(76) Inventors: TAKASHI SAKOH, TOKYO (JP); FUMIKI AISOU, TOKYO (JP)

Correspondence Address: FOLEY & LARDNER, WASHINGTON HARBOUR, 3000 K STREET NW, SUITE 500 PO BOX 25696, WASHINGTON, DC, 200078696

(21) Appl. No.: 09/138,535

(22) Filed: Aug. 24, 1998

(30) Foreign Application Priority Data
Dec. 25, 1995 (JP) 7-336803

(51) Int. Cl. H01L 21/36; H01L 21/8242; C30B 1/00; H01L 21/20

(52) U.S. Cl. 438/255; 438/398

(57) ABSTRACT

In a semiconductor device, a polycrystalline silicon layer is formed on a semiconductor substrate, and an HSG polycrystalline silicon layer is formed on the polycrystalline silicon layer. The HSG polycrystalline silicon is converted from an amorphous silicon layer.

### BACKGROUND OF THE INVENTION

1. Field of the Invention

The present invention relates to a semiconductor device such as a dynamic random access memory (DRAM) device having a stacked capacitor.

2. Description of the Related Art

Generally, in a DRAM cell, a stacked capacitor is comprised of a lower electrode layer, an upper electrode layer, and a dielectric layer therebetween. Recently, in order to increase the capacity of the stacked capacitor, various approaches have been known to make the surface of the lower electrode layer uneven.

In a prior art method for manufacturing a stacked capacitor, a contact hole is perforated in an insulating layer on a silicon substrate. Then, an amorphous silicon layer is buried in the contact hole. Then, the amorphous silicon layer is patterned to form a lower electrode. Then, a seeding operation is performed upon the amorphous silicon layer, so that a hemispherical-grain (HSG) polycrystalline silicon layer is grown in the amorphous silicon layer. This will be explained later in detal. For example, in a seeding operation, polycrystalline silicon nuclei are grown at a temperature of about 600° C. to 650° C. in a silane gas atmosphere, and thereafter, the amorphous silicon is completely converted into polycrystalline silicon at a temperature of 550° C. in a non-silane gas atmosphere (see: JP-A-5-304273).

In the above-described prior art method, in order to increase the capacitance of the stacked capacitor, more impurity atoms should be doped in the HSG polycrystalline silicon layer.

In the prior art manufacturing method, however, if the concentration of impurity atoms in the amorphous silicon layer is increased, the solid solution of impurities in the amorphous silicon layer is reduced during a low temperature heating process for an HSG process, impurities are segregated at an interface between the amorphous silicon layer and the silicon substrate. The segregated impurities are further diffused into the silicon substrate at a post stage heating process, so that impurity diffusion regions are further enlarged. Therefore, the isolation characteristics of cells are degraded. This adverse effect is distinguished when the integration is advanced. Therefore, the retention characteristics of DRAM devices including HSG type stacked capacitors are deteriorated. Thus, the manufacturing yield of DRAM devices including HSG type stacked capacitors is lowered.

### SUMMARY OF THE INVENTION

It is an object of the present invention to improve the manufacturing yield of a semiconductor device having an HSG polycrystalline silicon layer.

Another object is to provide a method for manufacturing the above-mentioned semiconductor device.

According to the present invention, in a semiconductor device, a polycrystalline silicon layer is formed on a semiconductor substrate, and an HSG polycrystalline silicon layer is formed on the polycrystalline silicon layer. The HSG polycrystalline silicon is converted from an amorphous silicon layer. Thus, the diffusion of impurities from the HSG polycrystalline silicon layer to the semiconductor substrate is suppressed by the polycrystalline silicon layer therebetween.

### BRIEF DESCRIPTION OF THE DRAWINGS

The present invention will be more clearly understood from the description as set forth below, as compared with the prior art, with reference to the accompanying drawings, wherein:

FIGS. 1A through 1E are cross-sectional views for explaining a prior art method for manufacturing DRAM cells;

FIG. 2 is a graph showing the capacitance-to-voltage (C-V) characteristics of the DRAM cell of FIG. 1;

FIG. 3 is a graph showing the retention characteristics of the prior art stacked capacitor of FIG. 1;

FIGS. 4A and 4B are diagrams showing the manufacturing yield of the prior art stacked capacitor of FIG. 1;

FIGS. 5A through 5E are cross-sectional views for explaining a first embodiment of the method for manufacturing DRAM cells according to the present invention;

FIGS. 6A and 6B are cross-sectional views illustrating modifications of the device of FIG. 5E;

FIGS. 7A through 7G are cross-sectional views for explaining a second embodiment of the method for manufacturing DRAM cells according to the present invention;

FIGS. 8A and 8B are cross-sectional views illustrating modification of the device of FIG. 7G;

FIGS. 9A through 9H are cross-sectional views for explaining a third embodiment of the method for manufacturing DRAM cells according to the present invention;

FIGS. 10A through 10K are cross-sectional views for explaining a fourth embodiment of the method for manufacturing DRAM cells according to the present invention;

FIGS. 11A and 11B are cross-sectional views illustrating modifications of the device of FIG. 10K;

FIG. 12 is a graph showing the retention characteristics of the stacked capacitor of according to the present invention; and

FIG. 13 is a diagram showing the manufacturing yield of the stacked capacitor according to the present invention.

### DESCRIPTION OF THE PREFERRED EMBODIMENTS

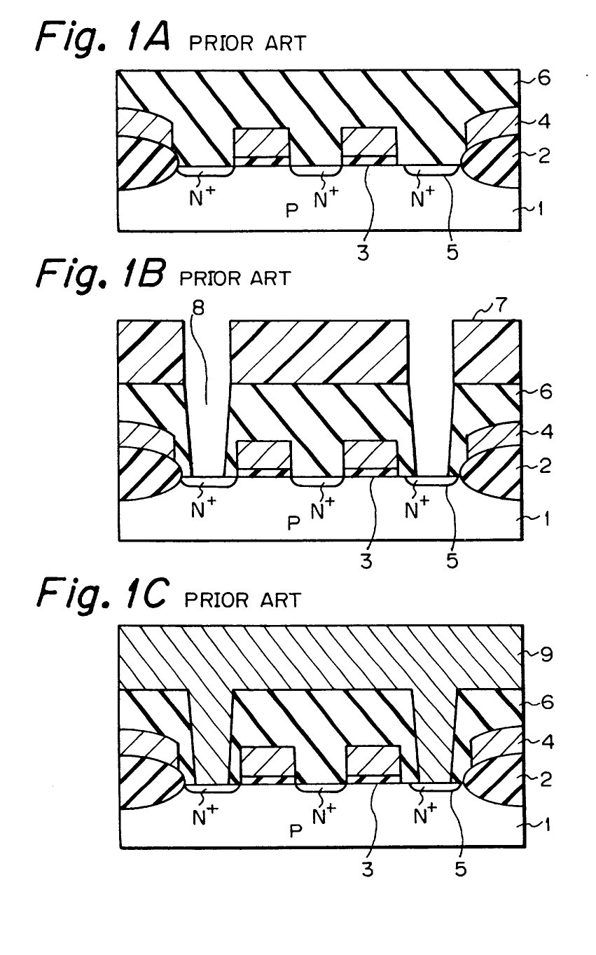

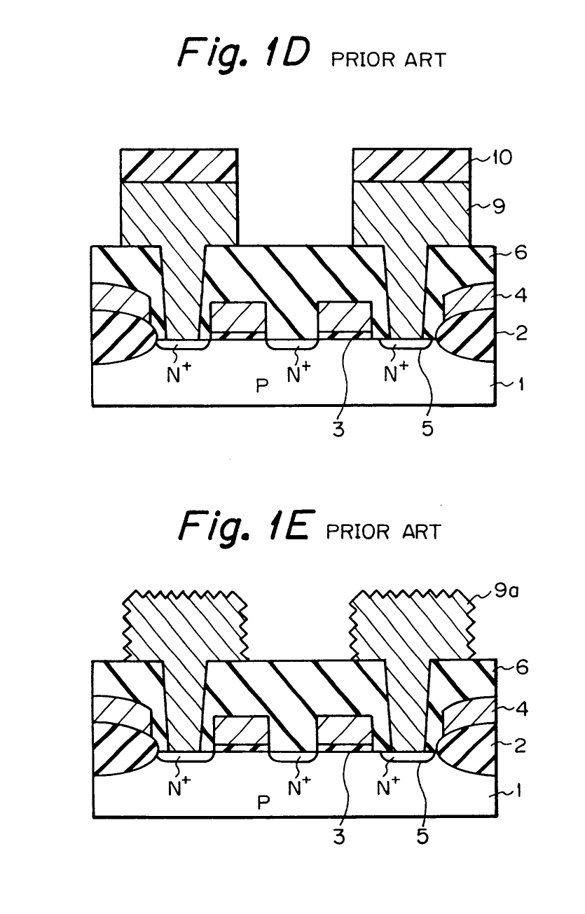

Before the description of the preferred embodiments, a prior art method for manufacturing DRAM cells will be explained with reference to FIGS. 1A through 1E, 2, 3A, 3B and 4.

First, referring to FIG. 1A, a P⁻-type monocrystalline silicon substrate 1 is thermally oxidized by using a local oxidation of silicon (LOCOS) process to grow a field silicon oxide layer 2 thereon. Also, a gate silicon oxide layer 3 is formed by thermally oxidizing the silicon substrate 1. Then, a polycrystalline silicon layer 4 is formed by using a chemical vapor deposition (CVD) process, and is patterned to form word lines. Then, N⁺-type impurity diffusion regions 5 are formed within the silicon substrate 1 in self-alignment with the polycrystalline silicon layer 4. Further, a boron-including phosphosilicate glass (BPSG) layer 6 is formed by a CVD process. Then, the BPSG layer 6 is annealled to flatten it.

Next, referring to FIG. 1B, a photoresist pattern layer 7 is formed by using a photolithography process, and the BPSG layer 6 is etched using the photoresist pattern layer 7 as a mask to perforate contact holes 8 therein. Then, the photoresist pattern layer 7 is removed.

Next, referring to FIG. 1C, a phosphorus-doped amorphous silicon layer 9 is deposited by using a low pressure CVD (LPCVD) process.

Next, referring to FIG. 1D, a photoresist pattern layer 10 is formed by using a photolithography process, and the amorphous silicon layer 9 is etched using the photoresist pattern layer 10 as a mask. Then, the photoresist pattern layer 10 is removed.

Finally, referring to FIG. 1E, an HSG polycrystalline silicon layer 9a is grown in the amorphous silicon layer 9. For example, the device is put in a silane gas atmosphere at a temperature of about 600° C. to 650° C., and thereafter, is in a non-silane gas atmosphere at a temperature of about 550° C. Thus, the HSG polycrystalline silicon layer 9a has an uneven surface. Then, a capacitor dielectric layer and a counter plate layer (not shown) are formed thereon to obtain a HSG type stacked capacitor having a large capacitance.

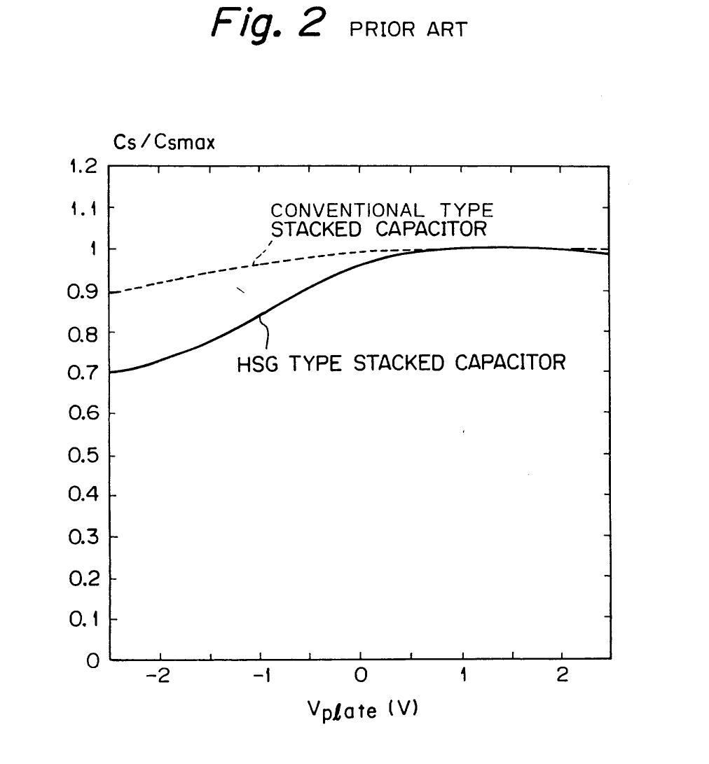

In FIG. 2, which shows C-V characteristics of the HSG type stacked capacitor obtained by the manufacturing method as shown in FIGS. 1A through 1E, about 0.5×10²⁰ phosphorous atoms/cm³ are doped in the HSG polycrystalline silicon layer 10a. Note that a dotted line shows C-V characteristics of a conventional type stacked capacitor, i.e., a non-HSG type stacked capacitor where about 0.5×10²⁰ phosphorous atoms/cm³ are also doped in a non-HSG type polycrystalline silicon layer. Therefore, in order to increase the capacitance of the HSG type stacked capacitor, more phosphorous atoms should be doped in the HSG type polycrystalline silicon layer 9a.

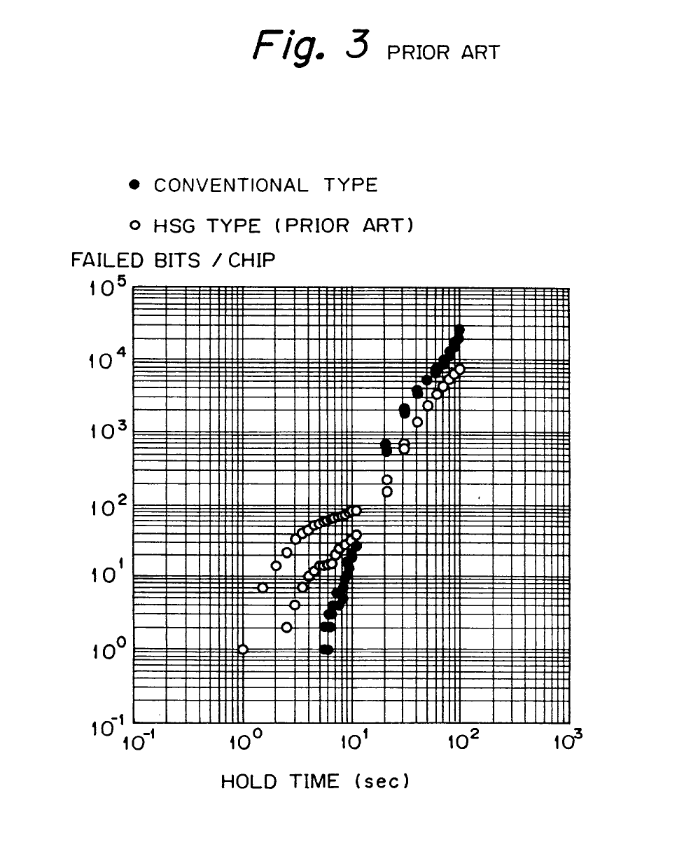

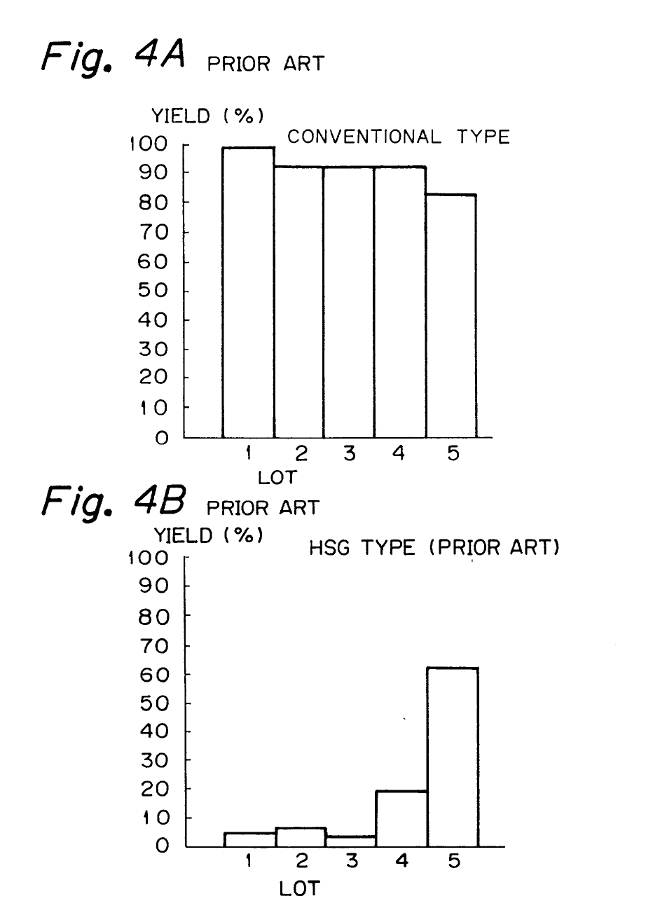

In the prior art manufacturing method, however, if the concentration of phosphorous atoms in the amorphous silicon layer 9 is increased, the solid solution of phosphorus in the amorphous silicon layer 9 is reduced during a low temperature heating process for an HSG process, phosphorus atoms are segregated at an interface between the amorphous silicon layer 9 and the BPSG layer 6 and at an interface between the amorphous silicon layer 9 and the silicon substrate 1. The segregated phosphorus atoms are further diffused into the silicon substrate 1 at a post stage heating process, so that the N⁺-type impurity diffusion regions 5 are further enlarged. Therefore, the isolation characteristics of cells are degraded. This adverse effect is distinguished when the integration is advanced. Therefore, as shown in FIG. 3, although the hold time of some of memory cells is increased, the hold time of other memory cells is decreased. As a result, the retention characteristics of DRAM devices including HSG type stacked capacitors are deteriorated as compared with those of DRAM devices including conventional type stacked capacitors. Thus, the manufacturing yield of DRAM devices including HSG type stacked capacitors as shown in FIG. 4B is lowered as compared with that of DRAM devices including conventional type stacked capacitors as shown in FIG. 4A.

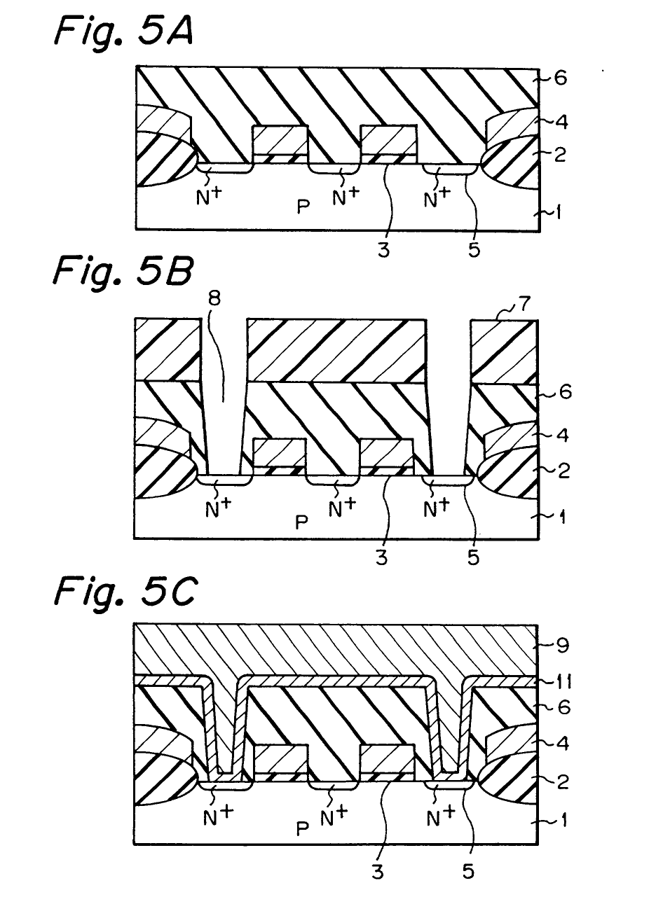

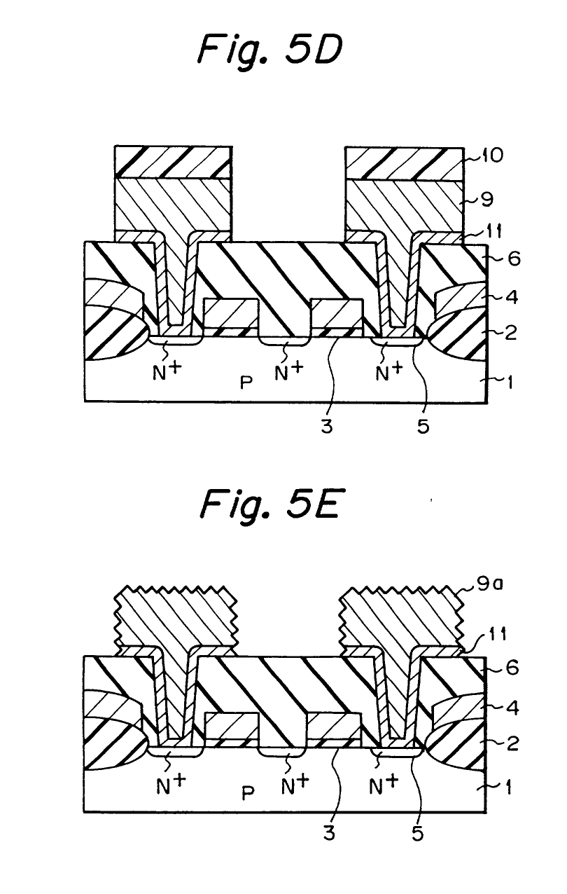

FIGS. 5A through 5E are cross-sectional views showing a first embodiment of DRAM cells according to the present invention.

First, referring to FIG. 5A, in the same way as in FIG. 1A, a P⁻-type monocrystalline silicon substrate 1 is thermally oxidized by using a LOCOS process to grow a field silicon oxide layer 2 thereon. Also, a gate silicon oxide layer 3 is formed by thermally oxidizing the silicon substrate 1. Then, a polycrystalline silicon layer 4 is formed by using a CVD process, and is patterned to form word lines. Then, N⁺-type impurity diffusion regions 5 are formed within the silicon substrate 1 in self-alignment with the polycrystalline silicon layer 4. Further, a BPSG layer 6 is formed by a CVD process.

Next, referring to FIG. 5B, in the same way as in FIG. 1B, a photoresist pattern layer 7 is formed by using a photolithography process, and the BPSG layer 6 is etched using the photoresist pattern layer 7 as a mask to perforate contact holes 8 therein. Then, the photoresist pattern layer 7 is removed.

Next, referring to FIG. 5C, in a similar way to that in FIG. 1C, a polycrystalline silicon layer 11 is deposited on the entire surface by using a CVD process. In this case, a small amount of impurities can be introduced into the polycrystalline silicon layer 11. Then, a phosphorus-doped amorphous silicon layer 9 is deposited by using a LPCVD process. In this case, the concentration of phosphorus atoms in the amorphous silicon layer 9 is about 6×10¹⁹ to 3×10²⁰ atoms/cm³, for example, 1×10²⁰ atoms/cm³.

Next, referring to FIG. 5D, in the same way as in FIG. 1D, a photoresist pattern layer 10 is formed by using a photolithography process, and the amorphous silicon layer 9 is etched by using the photoresist pattern layer 10 as a mask. Then, the photoresist pattern layer 10 is removed.

Finally, referring to FIG. 5E, in the same way as in FIG. 1E, an HSG polycrystalline silicon layer 9a is grown in the amorphous silicon layer 9. That is, the device is put in a vacuum chamber at a temperature of 550° C. to 900° C. Thus, the HSG polycrystalline silicon layer 9a has an uneven surface. Then, a capacitor dielectric layer and a counter plate layer (not shown) are formed thereon to obtain an HSG type stacked capacitor having a large capacitance.

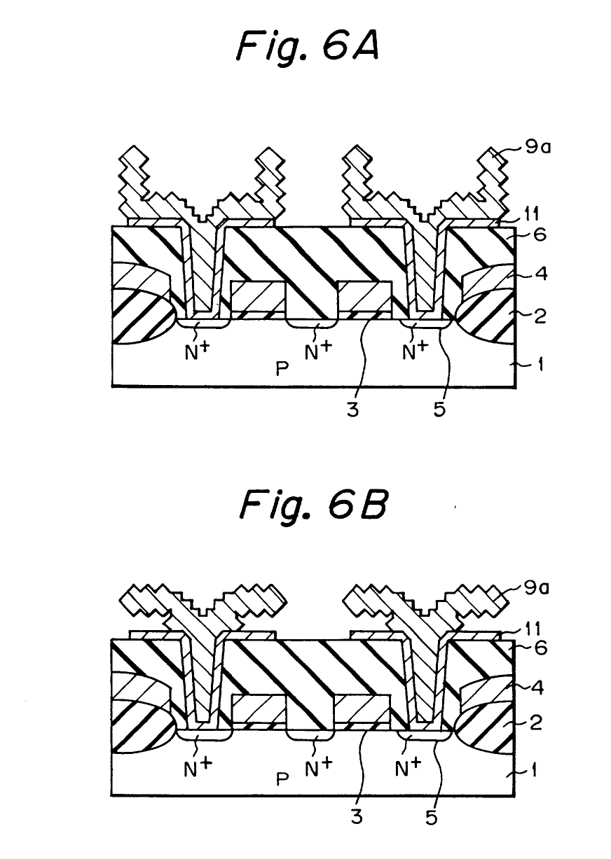

In the first embodiment, the HSG polycrystalline silicon layer 9a of FIG. 5E can be of a cylindrical shape as illustrated in FIG. 6A or of a fin shape as illustrated in FIG. 6B. Also, the HSG polycrystalline silicon layer 9a of FIG. 5E can be of a multi-cylindrical shape or of a multi-fin shape.

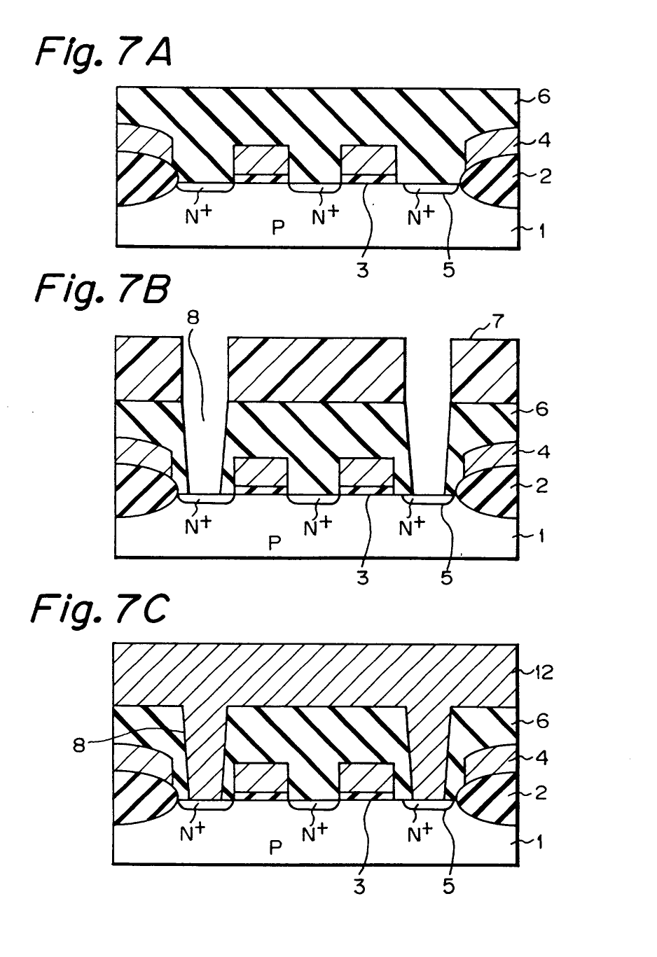

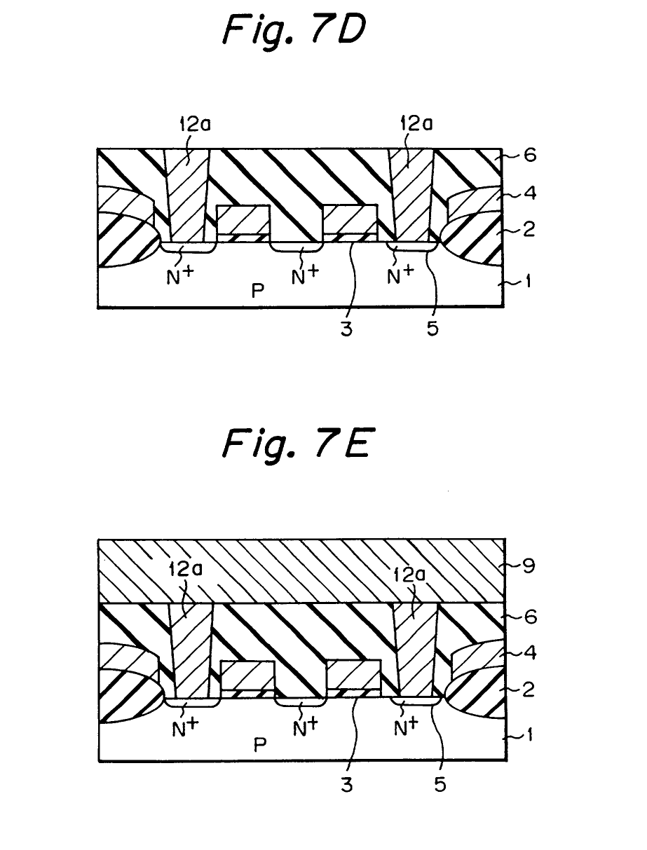

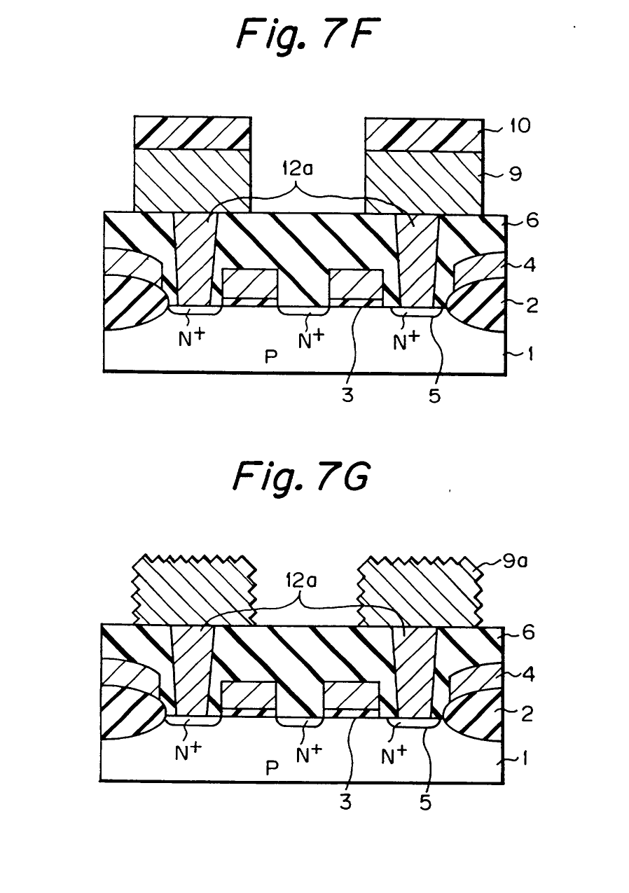

FIGS. 7A through 7E are cross-sectional views showing a second embodiment of DRAM cells according to the present invention.

First, referring to FIG. 7A, in the same way as in FIG. 1A, a P⁻-type monocrystalline silicon substrate 1 is thermally oxidized by using a LOCOS process to grow a field silicon oxide layer 2 thereon. Also, a gate silicon oxide layer 3 is formed by thermally oxidizing the silicon substrate 1. Then, a polycrystalline silicon layer 4 is formed by using a CVD process, and is patterned to form word lines. Then, N⁺-type impurity diffusion regions 5 are formed within the silicon substrate 1 in self-alignment with the polycrystalline silicon layer 4. Further, a BPSG layer 6 is formed by a CVD process. Then, the BPSG layer 6 is annealled to flatten it.

Next, referring to FIG. 7B, in the same way as in FIG. 1B, a photoresist pattern layer 7 is formed by using a photolithography process, and the BPSG layer 6 is etched using the photoresist pattern layer 7 as a mask to perforate contact holes 8 therein. Then, the photoresist pattern layer 7 is removed.

Next, referring to FIG. 7C, in a similar way to that in FIG. 1C, a polycrystalline silicon layer 12 is deposited on the entire surface by using a CVD process. In this case, the polycrystalline silicon layer 12 is sufficiently buried in the contact holes 8. Also, a small amount of impurities can be introduced into the polycrystalline silicon layer 12.

Next, referring to FIG. 7D, the polycrystalline silicon layer 12 is etched back by a dry etching process or a wet etching process. As a result, polycrystalline silicon plugs 12a are formed in the contact holes 8.

Next, referring to FIG. 7E, a phosphours-doped amorphous silicon layer 9 is deposited by using a LPCVD process. In this case, the concentration of phosphorus atoms in the amorphous silicon layer 9 is about 6×10¹⁹ to 3×10²⁰ atoms/cm³, for example, 1×10²⁰ atoms/cm³.

Next, referring to FIG. 7F, in the same way as in FIG. 1D, a photoresist pattern layer 10 is formed by using a photolithography process, and the amorphous silicon layer 9 is etched using the photoresist pattern layer 10 as a mask. Then, the photoresist pattern layer 10 is removed.

Finally, referring to FIG. 7G, in the same way as in FIG. 1E, an HSG polycrystalline silicon layer 9a is grown in the amorphous silicon layer 9. That is, the device is put in a vacuum chamber at a temperature of 550° C. to 900° C. Thus, the HSG polycrystalline silicon layer 9a has an uneven surface. Then, a capacitor dielectric layer and a counter plate layer (not shown) are formed thereon to obtain an HSG type stacked capacitor having a large capacitance.

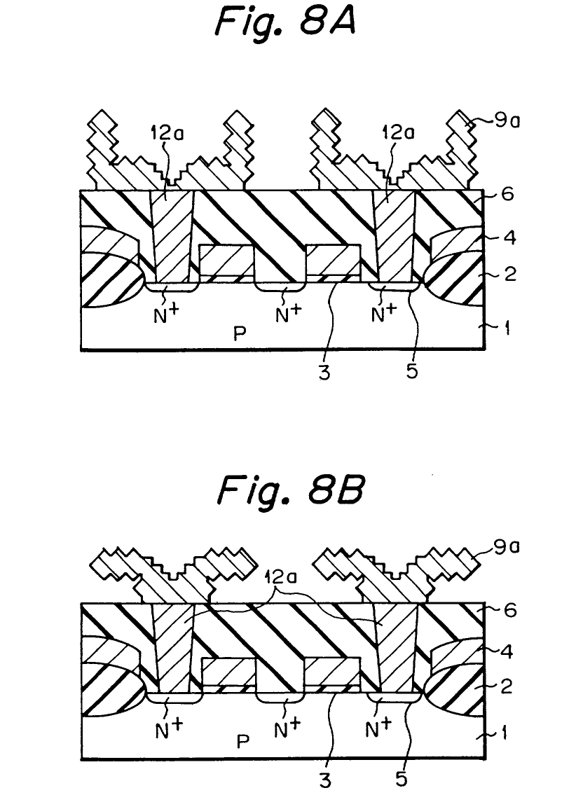

Also, in the second embodiment, the HSG polycrystalline silicon layer 9a of FIG. 7G can be of a cylindrical shape as illustrated in FIG. 8A or of a fin shape as illustrated in FIG. 8B. Also, the HSG polycrystalline silicon layer 9a of FIG. 7G can be of a multi-cylindrical shape or of a multi-fin shape.

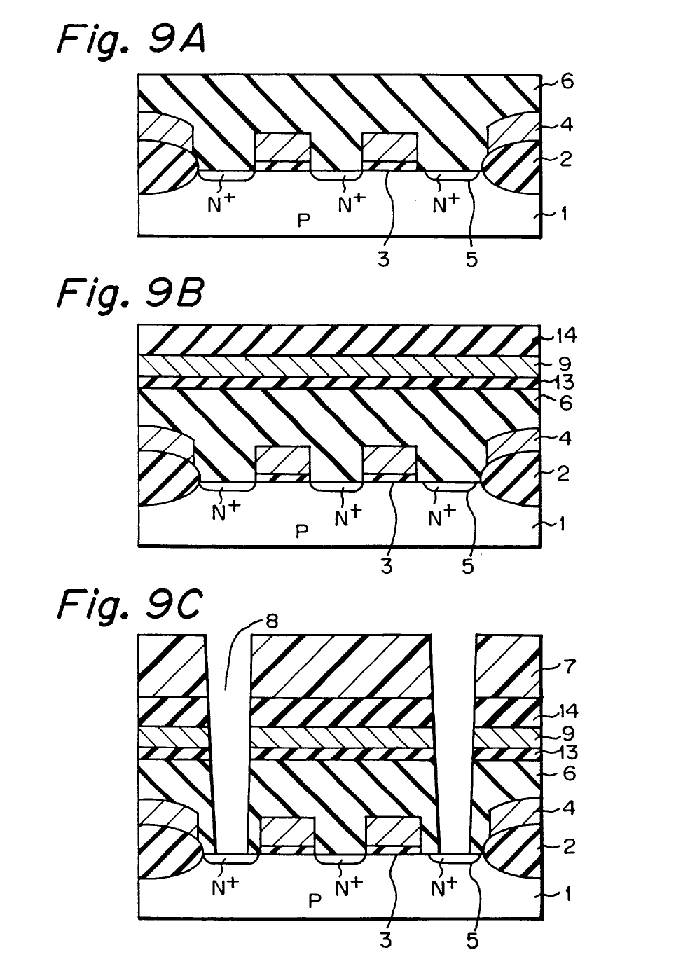

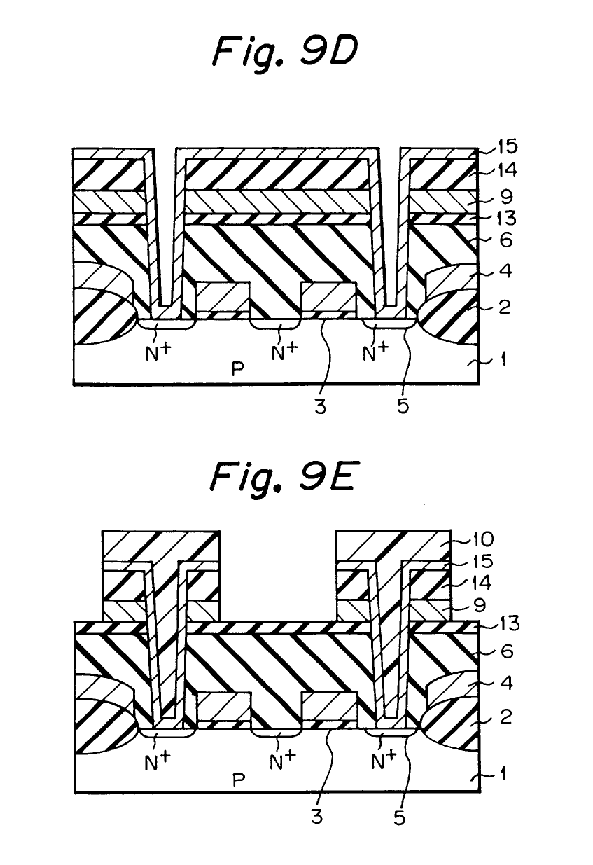

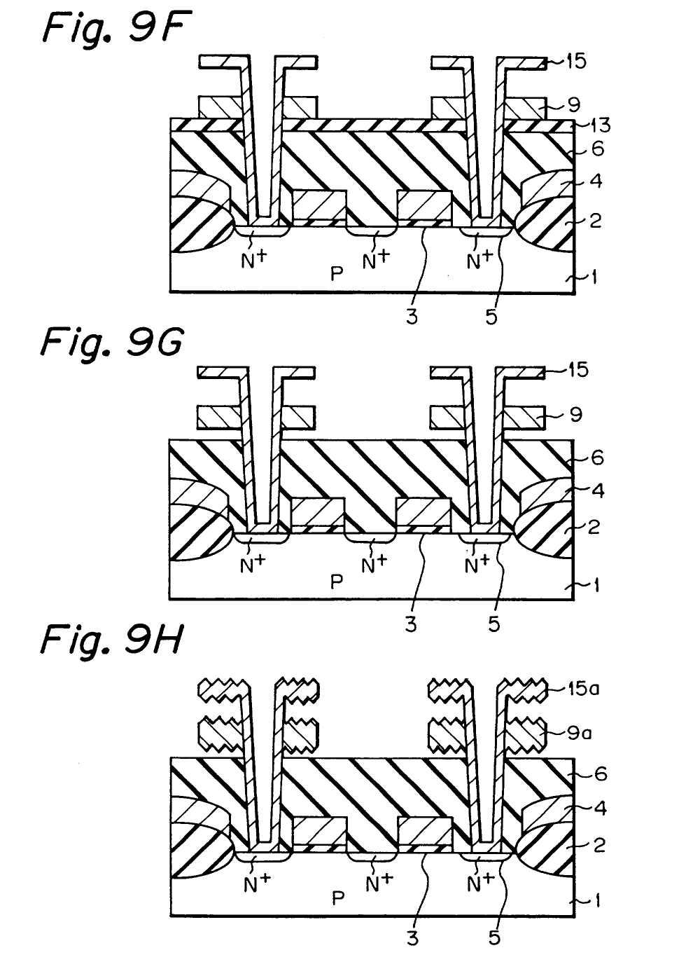

FIGS. 9A through 9H are cross-sectional views showing a third embodiment of DRAM cells according to the present invention.

First, referring to FIG. 9A, in the same way as in FIG. 1A, a P⁻-type monocrystalline silicon substrate 1 is thermally oxidized by using a LOCOS process to grow a field silicon oxide layer 2 thereon. Also, a gate silicon oxide layer 3 is formed by thermally oxidizing the silicon substrate 1. Then, a polycrystalline silicon layer 4 is formed by using a CVD process, and is patterned to form word lines. Then, N⁺-type impurity diffusion regions 5 are formed within the silicon substrate 1 in self-alignment with the polycrystalline silicon layer 4. Further, a BPSG layer 6 is formed by a CVD process. Then the BPSG layer 6 is annealled to flatten it.

Next, referring to FIG. 9B, a silicon nitride layer 13 serving as an etching stopper, a phosphorus-doped amorphous silicon layer 9, and a silicon oxide layer 14 serving as a spacer are deposited on the entire surface. In this case, the concentration of phosphorus atoms in the amorphous silicon layer 9 is about 6×10¹⁹ to 3×10²⁰ atoms/cm³, for example, 1×10²⁰ atoms/cm³.

Next, referring to FIG. 9C, in a similar way to that in FIG. 1B, a photoresist pattern layer 7 is formed by using a photolithography process, and the silicon oxide layer 14, the amorphous silicon layer 9, the silicon nitride layer 13 and the BPSG layer 6 are sequentially etched by using the photoresist pattern layer 7 as a mask to perforate contact holes 8 therein. Then, the photoresist pattern layer 7 is removed.

Next, referring to FIG. 9D, an undoped amorphous silicon layer 15 is deposited on the entire surface by using a LPCVD process.

Next, referring to FIG. 9E, in a similar way to that in FIG. 1D, a photoresist pattern layer 10 is formed by using a photolithography process, and, the undoped amorphous silicon layer 15, the silicon oxide layer 14 and the phosphorus-doped amorphous silicon layer 9 are sequentially etched by using the photoresist pattern layer 10 as a mask. Then, the photoresist pattern layer 10 is removed.

Next, referring to FIG. 9F, the silicon oxide layer 14 is etched by using the silicon nitride layer 13 as an etching stopper.

Next referring to FIG. 9G, the silicon nitride layer 13 is etched by using the PSG layer 6 as an etching stopper.

Finally, referring to FIG. 9H, in the same way as in FIG. 1E, an HSG polycrystalline silicon layer 9a is grown in the phosphorus-doped amorphous silicon layer 9, and simultaneously, an HSG polycrystalline silicon layer 15a is grown in the undoped amorphous silicon layer 15. That is, the device is put in a vacuum chamber at a temperature of 550° C. to 900° C. Thus, the HSG polycrystalline silicon layers 9a and 15a have uneven surfaces. Then, a capacitor dielectric layer and a counter plate layer (not shown) are formed thereon to obtain an HSG type stacked capacitor having a large capacitance.

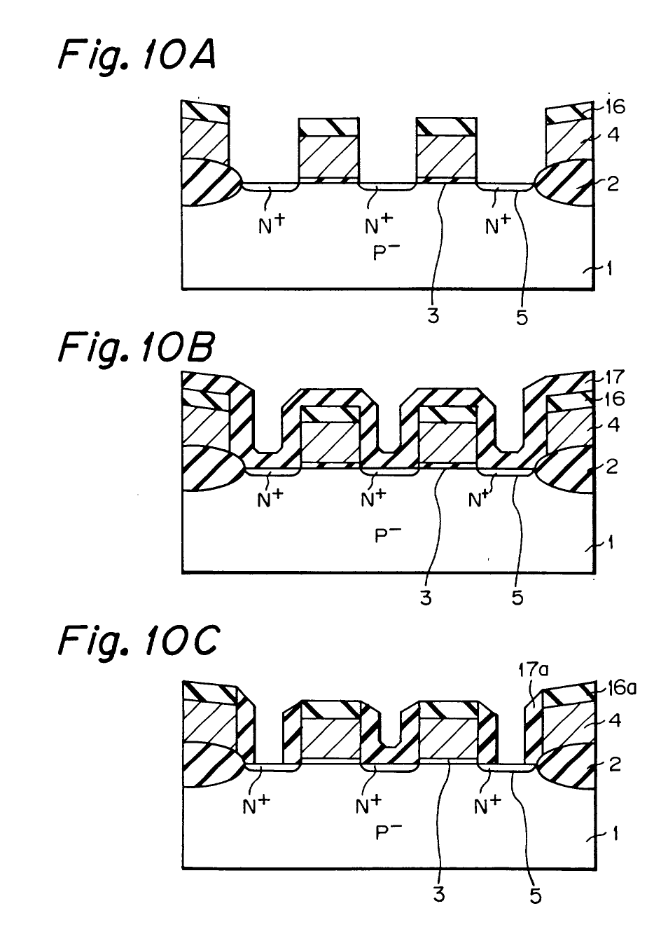

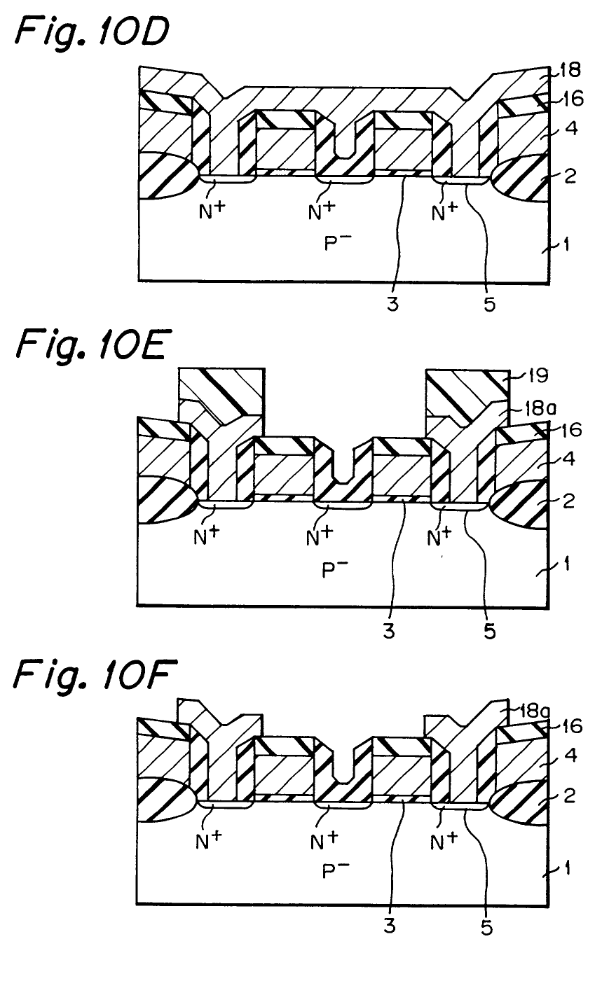

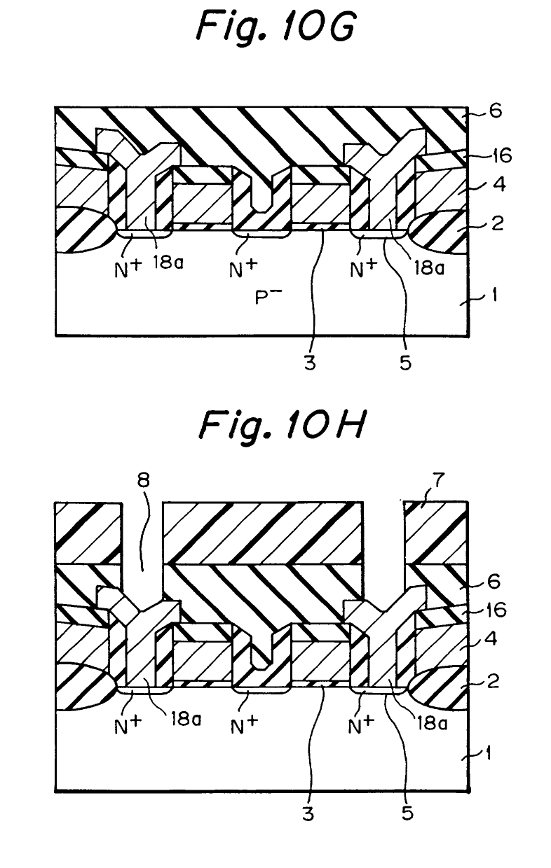

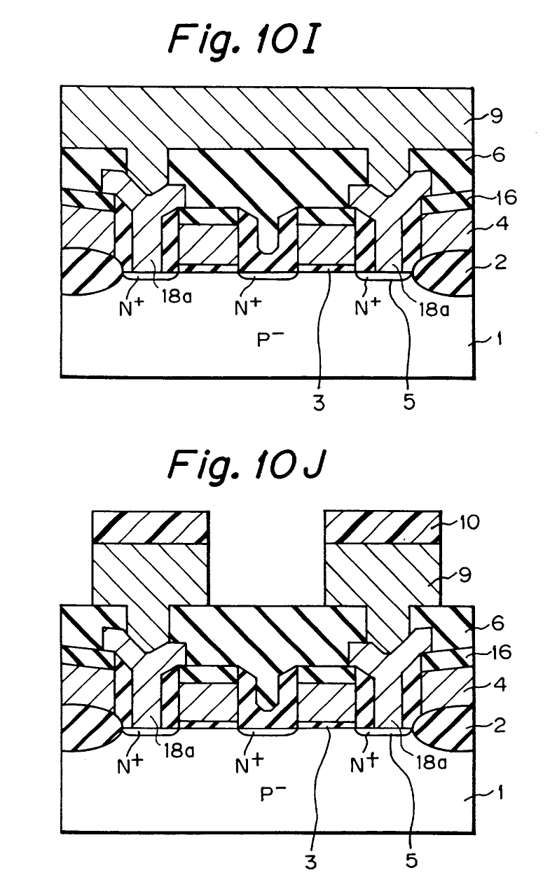

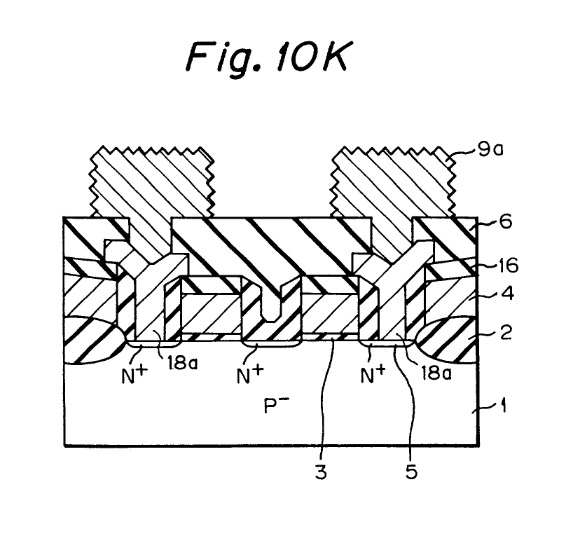

FIGS. 10A through 10K are cross-sectional views showing a fourth embodiment of DRAM cells according to the present invention.

First, referring to FIG. 10A, a P⁻-type monocrystalline silicon substrate 1 is thermally oxidized by using a LOCOS process to grow a field silicon oxide layer 2 thereon. Also, a gate silicon oxide layer 3 is formed by thermally oxidizing the silicon substrate 1. Then, a polycrystalline silicon layer 4 and a silicon oxide layer 16 are formed by using a CVD process, and are patterned to form word lines. Then, N⁺-type impurity diffusion regions 5 are formed within the silicon substrate 1 in self-alignment with the polycrystalline silicon layer 4 and the silicon oxide layer 16.

Next, referring to FIG. 10B, an insulating layer 17 made of silicon oxide or silicon nitride is formed on the entire surface.

Next, referring to FIG. 10C, the insulating layer 17 is etched back, so that sidewall insulating layers 17a are left on the sidewalls of the word lines.

Next, referring to FIG. 10D, a polycrystalline silicon layer 18 is deposited by a CVD process on the entire surface. In this case, a small amount of impurities can be introduced into the polycrystalline silicon layer 18.

Next, referring to FIG. 10E, a photoresist pattern layer 19 is formed by a photolithography process, and the polycrystalline silicon layer 18 is etched by using the photoresist pattern layer 19 as a mask. As a result, a contact pad layer 18a is left.

Next, referring to FIG. 10F, the photoresist pattern layer 19 is removed.

Next, referring to FIG. 10G, in the smae way as in FIG. 1C, a BPSG layer 6 is formed by a CVD process. Then the BPSG layer 6 is annealled to flatten it.

Next, referring to FIG. 10H, in the same way as in FIG. 1B, a photoresist pattern layer 7 is formed by using a photolithography process, and the BPSG layer 6 is etched by using the photoresist pattern layer 7 as a mask to perforate contact holes 8 therein. Then, the photoresist pattern layer 7 is removed.

Next, referring to FIG. 10I, in the same way as in FIG. 1C, a phosphorus-doped amorphous silicon layer 9 is deposited by using a LPCVD process. In this case, the concentration of phosphorus atoms in the amorphous silicon layer 9 is about 6×10¹⁹ to 5×10²⁰ atoms/cm³, for example, 1×10²⁰ atoms/cm³.

Next, referring to FIG. 10J, in the same way as in FIG. 1D, a photoresist pattern layer 10 is formed by using a photolithography process, and the amorphous silicon layer 9 is etched using the photoresist pattern layer 10 as a mask. Then, the photoresist pattern layer 1D is removed.

Finally, referring to FIG. 10K, in the same way as in FIG. 1E, an HSG polycrystalline silicon layer 9a is grown in the amorphous silicon layer 9. That is, the device is put in a vacuum chamber at a temperature of 550° C. to 900° C. Thus, the HSG polycrystalline silicon layer 9a has an uneven surface. Then, a capacitor dielectric layer and a counter plate layer (not shown) are formed thereon to obtain an HSG type stacked capacitor having a large capacitance.

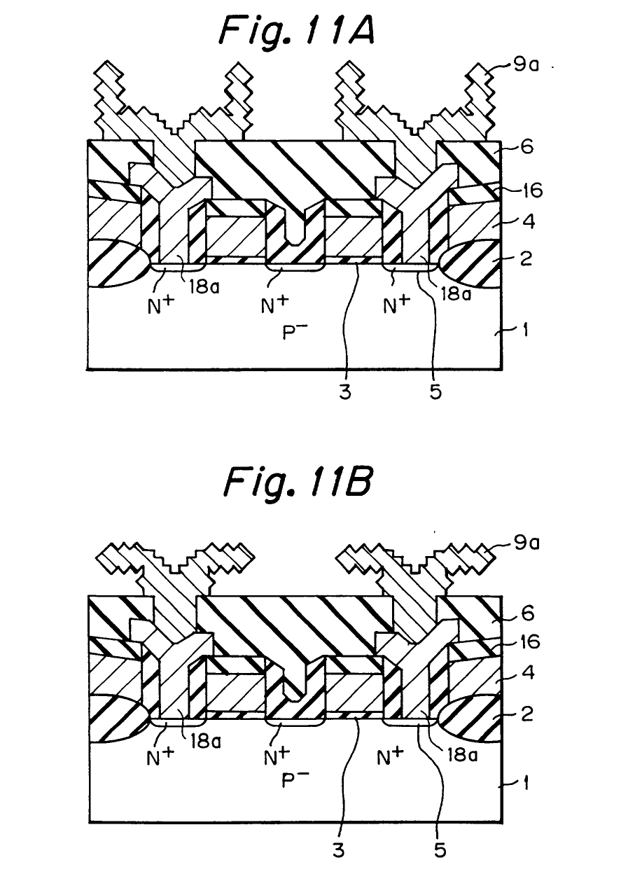

In the fourth embodiment, the HSG polycrystalline silicon layer 9a of FIG. 10K can be of a cylindrical shape as illustrated in FIG. 11A or of a fin shape as illustrated in FIG. 11B. Also, the HSG polycrystalline silicon layer 9a of FIG. 11K can be of a multi-cylindrical shape or of a multi-fin shape.

In the above-described embodiments, note that atoms such as arsenic atoms other than phosphorus atoms can be introduced into the amorphous silicon layer 9.

Further, in the above-described embodiments, in a process for converting amorphous silicon into HSG type polycrystalline silicon, a polycrystalline silicon layer including an HSG polycrystalline silicon on the surface thereof can be formed by using an LPCVD process.

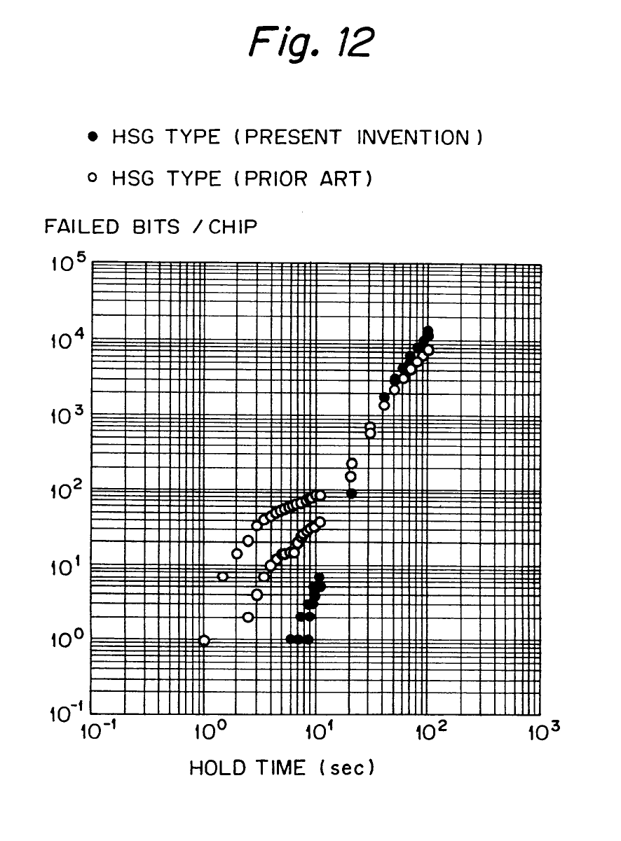

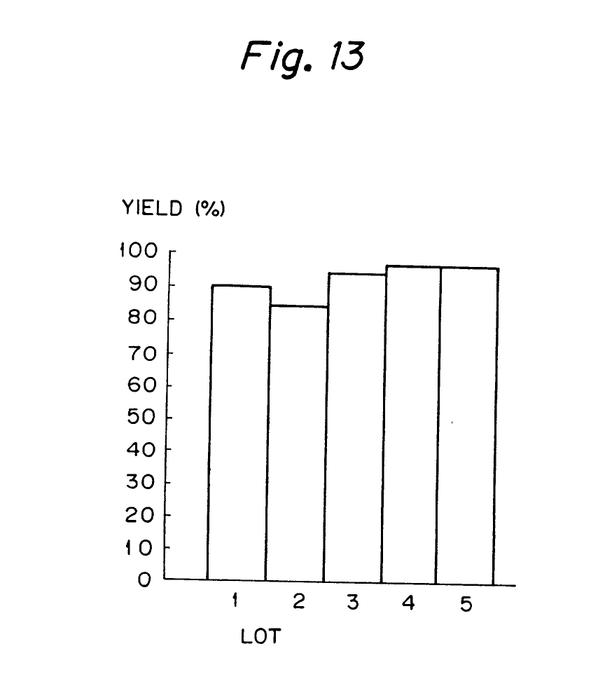

Thus, in the above-described embodiments, since the polycrystalline silicon layer 11 (12a, 18a) or the undoped amorphous silicon layer 15 is interposed as a buffer layer between the doped amorphous silicon layer 9 and the silicon substrate 1, even if the concentration of phosphorous atoms in the amorphous silicon layer 9 is increased, so that the solid solution of phosphorus in the amorphous silicon layer 9 is reduced during a low temperature heating process for an HSG process, impurities segregated at the interface between the amorphous silicon layer 9 and the BPSG layer 6 and at the interface between the amorphous silicon layer 9 and the buffer layer phosphorus are hardly diffused into the silicon substrate 1 at a post stage heating process, so that the N⁺-type impurity diffusion regions 5 are hardly enlarged. Therefore, the isolation characteristics of cells are not degraded. Therefore, as shown in FIG. 12, the hold time of most of memory cells is increased. As a result, the retention characteristics of DRAM devices including HSG type stacked capacitors according to the present invention can be improved. Thus, the manufacturing yield of DRAM devices including HSG type stacked capacitors accoding to the present invention can be improved as shown in FIG. 13.

As explained hereinabove, according to the present invention, the manufacturing yield of DRAM devices can be improved.

1. A semiconductor device comprising:
a semiconductor substrate;
a polycrystalline silicon layer formed on said semiconductor substrate; and
an HSG polycrystalline silicon layer formed on said polycrystalline silicon layer, said HSG polycrystalline silicon being converted from an amorphous silicon layer.

2. The device as set forth in claim 1, wherein said HSG polycrystalline silicon layer includes impurities having a concentration of approximately 6×10¹⁹ to 3×10²⁰ atoms/cm³.

3. The device as set forth in claim 1, wherein said polycrystalline silicon layer is in contact with an impurity diffusion region formed within said semiconductor substrate.

4. The device as set forth in claim 1, further comprising an insulating layer formed on said semiconductor substrate, a contact hole being formed in said insulating layer,
said polycrystalline silicon layer being formed in the contact hole of said insulating layer.

5. The device as set forth in claim 1, further comprising an insulating layer formed on said semiconductor substrate, a contact hole being formed in said insulating layer,
said polycrystalline silicon layer being buried as a plug in the contact hole of said insulating layer.

6. The device as set forth in claim 1, further comprising an insulating layer formed on said semiconductor substrate, a contace hole being formed in said insulating layer,
said polycrystalline silicon layer being another HSG polycrystalline silicon layer converted from another amorphous silicon layer formed in the contact hole of said insulating layer.

7. The device as set forth in claim 1, further comprising:
a first insulating layer formed on said semiconductor substrate, a first contact hole being formed within said first insulating layer, said polycrystalline silicon layer being buried as a contact pad in said first contact hole;
a second insulating layer formed on said polycrystalline silicon layer, a second contact hole being formed within said second insulating layer,
said HSG polycrystalline silicon layer being buried in said second contact hole.

8. The device as set forth in claim 1, wherein said HSG polycrystalline silicon layer constitutes a capacitor lower electrode.

9. A semiconductor device comprising:
a semiconductor substrate;
an insulating layer formed on said semiconductor substrate, a contact hole being formed within said insulating layer;
an undoped HSG polycrystalline silicon layer formed in said contact hole and protruding from said insulating layer; and
a doped HSG polycrystalline silicon layer formed over said insulating layer and connected to said undoped HSG polycrystalline silicon layer.

10. The device as set forth in claim 9, wherein said doped HSG polycrystalline silicon layer includes impurities having a concentration of approximately 6×10¹⁹ to 3×10²⁰ atoms/cm³.

11. The device as set forth in claim 9, wherein said undoped HSG polycrystalline silicon layer is in contact with an impurity diffusion region formed within said semiconductor substrate.

12. The device as set forth in claim 9, wherein said HSG polycrystalline silicon layer constitutes a capacitor lower electrode.

13. A method for manufacturing a semiconductor devic, comprising the steps of:
forming a polycrystalline silicon layer on a semiconductor substrate;
forming an impurity-doped amorphous silicon layer on said polycrystalline silicon layer; and
converting said impurity-doped amorphous silicon layer into an HSG polycrystalline silicon layer.

14. The method as set forth in claim 13, further comprising the steps of:
forming an insulating layer on said semiconductor substrate; and
perforating a contact hole within said insulating layer,
said polycrystalline silicon layer forming step comprising a step of forming said polycrystalline silicon layer on said insulating layer including said contact hole.

15. The method as set forth in claim 13, further comprising the steps of:
forming an insulating layer on said semiconductor substrate; and
perforating a contact hole within said insulating layer,
said polycrystalline silicon layer forming step comprising the steps of:
forming said polycrystalline silicon layer on said insulating layer including said contact hole; and
etching back said polycrystalline silicon layer so that a polycrystalline silicon plug is buried in said contact hole.

16. The method as set forth in claim 13, further comprising the steps of:
forming a conductive layer; and
forming a sidewall insulating layer on sidewalls of said conductive layer,
said polycrystalline silicon layer forming step comprising the steps of:
forming said polycrystalline silicon layer on said sidewall insulating layer; and
patterning said polycrystalline silicon layer, so that a polycrystalline silicon pad is formed in said contact hole.

17. The method as set forth in claim 14, further comprising the steps of:
forming an insulating layer on said polycrystalline silicon pad; and
perforating a contact hole within said insulating layer,
said impurity-doped amorphous silicon layer forming step comprising a step of forming said impurity-doped amorphous silicon layer on said polycrystalline silicon pad within said contact hole.

18. The method as set forth in claim 13, further comprising a step of forming an impurity diffusion region within said semiconductor substrate, said impurity diffusion region being connected to said polycrystalline silicon layer.

19. The method as set forth in claim 13, wherein said impurity-doped polycrystalline silicon layer includes impurities having a concentration of approximately 6×10¹⁹ to 3×10²⁰ atoms/cm³.

20. A method for manufacturing a semiconductor device, comprising the steps of:
forming a first insulating layer on a semiconductor substrate:
forming a second insulating layer on said first insulating layer:
forming a doped amorphous silicon layer on said second insulating layer:
forming a third insulating layer on said doped amorphous silicon layer;
perforating a contact hole in said third insulating layer, said doped amorphous silicon layer, said second insulating layer and said first insulating layer;
forming an undoped amorphous silicon layer in said contact hole;
patterning said undoped amorphous silicon layer, said third insulating layer and said doped amorphous silicon layer;
removing said third insulating layer and said second insulating layer; and
converting said undoped amorphous silicon layer and said doped amorphous silicon layer into an HSG undoped polycrystalline silicon layer and an HSG doped polycrystalline silicon layer, respectively.

21. The method as set forth in claim 20, further comprising a step of forming an impurity diffusion region within said semiconductor substrate, said impurity diffusion region being connected to said HSG undoped polycrystalline silicon layer.

22. The method as set forth in claim 20, wherein said doped polycrystalline silicon layer includes impurities having a concentration of approximately 6×10¹⁹ to 3×10²⁰ atoms/cm³.
